(19) United States
(12) Patent Application Publication
(10) Pub. No.: US 2007/0008040 A1
(43) Pub. Date: Jan. 11, 2007

(54) Digital phase locked loop, method for controlling a digital phase locked loop and method for generating an oscillator signal

(76) Inventors: Thomas Mayer, Linz (AT); Stefan Herzinger, Sauerlach (DE); Burkhard Neurauter, Linz (AT); Gunter Marzinger, Linz (AT)

Correspondence Address: ESCHWEILER & ASSOCIATES, LLC;NATIONAL CITY BANK BUILDING, 629 EUCLID AVE., SUITE 1000, CLEVELAND, OH, 44114, US

(21) Appl. No.: 11/477,262

(22) Filed: Jun. 29, 2006

(30) Foreign Application Priority Data
Jun. 29, 2005 (DE) DE102005030356.0

(51) Int. Cl. H03L 7/085

(52) U.S. Cl. 331/1 A

(57) ABSTRACT

A digital phase locked loop includes a digital phase detector, a downstream digital filter and an oscillator. In addition, a frequency divider resides in a feedback path and has an actuating input for setting a divider ratio, the input of which is connected to the oscillator and the phase detector. The phase locked loop comprises a sigma-delta modulator having a data input for supplying a data word and having an actuating output for supplying a frequency setting word to the actuating input of the frequency divider. The data word is configured such that the sigma-delta modulator generates jitter in the frequency setting word, with the result that the signal which is applied to the feedback input of the phase detector is not constant over a relatively long period of time.

### REFERENCE TO RELATED APPLICATIONS

This application claims the benefit of the priority date of German application DE 10 2005 030 356.0, filed on Jun. 29, 2005, the contents of which are herein incorporated by reference in their entirety.

### FIELD OF THE INVENTION

The invention relates to a digital phase locked loop, to a method for controlling a digital phase locked loop, and to a method for generating an oscillator signal.

### BACKGROUND OF THE INVENTION

Increasing miniaturization in the field of mobile radio, in particular in mobile communication devices, is resulting in the development of radiofrequency assemblies with a very high integration density. Many of the radiofrequency assemblies required have, in the meantime, been produced in the form of integrated circuits in semiconductors using different process technologies. In this case, easy portability of the various radiofrequency assemblies to ever finer semiconductor structures is increasingly strived for, a process which is referred to as “shrinking”. A reduction in the space used by the integrated circuits as a result of such porting enables a higher yield during production and a lower power consumption during operation of the integrated circuits.

Typical radiofrequency assemblies which are manufactured in the form of integrated circuits are, inter alia, phase locked loops (PLLs), voltage-controlled or digitally controllable oscillators (VCOs, DCOs) and power amplifier assemblies. Some of these assemblies have already been implemented in a single semiconductor body.

Implementing the assemblies using purely digital circuits is expedient especially from the point of view of easy portability to new manufacturing technologies and the higher integration density required. On the one hand, digital circuits can be easily adapted to new manufacturing technologies on account of their signal processing and, on the other hand, can be calibrated in a simpler manner in order to compensate for manufacturing tolerances. In addition, in contrast to component groups for analog signal processing, porting purely digital circuits to new or more finely patterned semiconductors does not require any complex adaptation to the new process technology.

In this respect, stabilizing a so-called digitally controlled oscillator in a completely digital manner using a digital phase locked loop has recently proven to be suitable. The term “digital phase locked loop” is understood below as meaning a phase locked loop in which the control signal which is used to set the digitally controlled oscillator is generated using digital signal processing. In the case of conventional digital phase locked loops, a so-called digital phase detector can be used to stabilize the digitally controllable oscillator.

In this case, the digital phase detector digitizes the difference between the phase of a reference signal and the phase of the feedback oscillator signal. In the case of the feedback oscillator signal being at a frequency that is not an integer multiple of the reference frequency, the resultant phase error signal forms a beat and is detected by a plurality of quantization stages in the digital phase detector. As a result, good control and thus good stabilization of the oscillator can be achieved.

However, in the case of frequency synthesis in which the frequency of the feedback oscillator signal corresponds to an integer multiple of the frequency of the reference signal, the error signal is essentially constant and there is no beat. As a result, the phase error signal is processed using only a single quantization stage in the digital phase detector. Under unfavorable circumstances, this may result in a linearity problem and may impair the stability behavior of the control loop.

### SUMMARY OF THE INVENTION

The following presents a simplified summary in order to provide a basic understanding of one or more aspects of the invention. This summary is not an extensive overview of the invention, and is neither intended to identify key or critical elements of the invention, nor to delineate the scope thereof. Rather, the primary purpose of the summary is to present one or more concepts of the invention in a simplified form as a prelude to the more detailed description that is presented later.

In one embodiment of the invention, a digital phase locked loop comprises a digital phase detector having a feedback input, a reference input and an actuating output. The digital phase detector is configured to compare the phases of signals that are applied to the input and supply an actuating signal that is derived from the phase difference to the actuating output. A digital filter is coupled to the actuating output of the digital phase detector. The actuating input of an oscillator that can be tuned to discrete values is connected to an output of the digital filter. The oscillator is configured to supply a radiofrequency signal whose frequency depends on an actuating word that is supplied to the actuating input. The digital phase locked loop also comprises a feedback path having a frequency divider which has an actuating input for setting its divider ratio. The input of the frequency divider is connected to the output of the oscillator, and the output of the frequency divider is connected to the feedback input of the digital phase detector. Provision is also made of a sigma-delta modulator having a data input for supplying a data word and having an actuating output for supplying a frequency setting word comprising the data word to the actuating input of the frequency divider.

According to one embodiment of the invention, the data word that is constantly supplied over a particular period of time is configured so that the frequency setting word generated by the sigma-delta modulator is not constant during this period of time but rather changes between at least two different values. The data word is therefore configured so that the sigma-delta modulator always generates jitter in the frequency setting word during operation, with the result that the signal which is applied to the feedback input of the phase detector is not constant over a relatively long period of time. In other words, in one embodiment the data word which is supplied to the sigma-delta modulator is configured in such a manner that precisely defined jitter is introduced into the frequency setting word. A frequency change in the signal that is applied to the feedback input of the phase detector is thus also generated.

The precisely defined jitter or additional jitter within the frequency setting word prevents a signal which is applied to the feedback input of the phase detector from being temporally constant over a relatively long period of time and the phase detector thus no longer generates a beat in the case of an integer multiple of the frequency of the reference signal. In other words, as a result of the invention, the phase detector generates an error signal which is not constant over time and is thus processed using a plurality of quantization stages in the phase detector.

The result is that a digital phase locked loop in accordance with the invention has sufficient stability even in the case of output frequencies that correspond to an integer multiple of a reference frequency.

In order to control a digital phase detector, a frequency setting word is thus supplied to a frequency divider in a feedback path of the digital phase locked loop, the setting word changing over between at least two values. This prevents the feedback signal being at a frequency that is constant over a relatively long period of time.

### BRIEF DESCRIPTION OF THE DRAWINGS

The invention will be explained in more detail below using a plurality of exemplary embodiments and with reference to the figures. Functionally similar and operatively similar components bear the same reference symbols.

In the figures:

FIG. 1 is a block diagram illustrating a digital phase locked loop according to one embodiment of the invention,

FIG. 2 is a block/schematic diagram illustrating one embodiment of the digital phase detector,

FIG. 3 is a block/schematic diagram illustrating one embodiment of a frequency divider circuit in a feedback path of the digital phase locked loop,

FIG. 4 is a schematic diagram illustrating one embodiment of a digital filter,

FIG. 5 is a schematic diagram illustrating one exemplary embodiment of a cascaded sigma-delta modulator, and

FIG. 6 is a schematic diagram illustrating one embodiment of a digitally controllable oscillator.

### DETAILED DESCRIPTION OF THE INVENTION

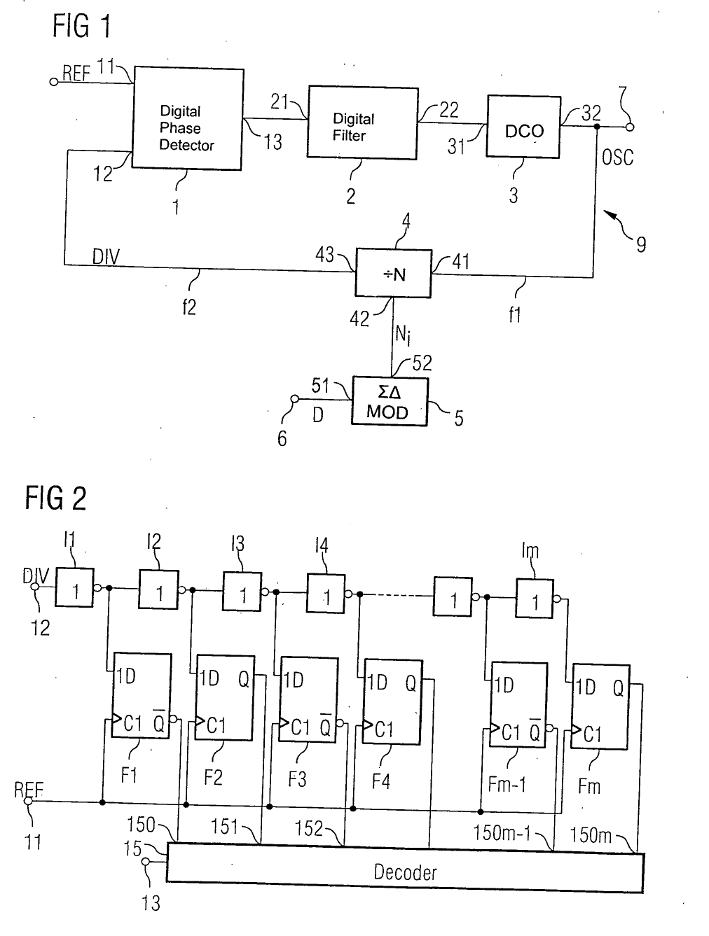

FIG. 1 shows a block diagram of a digital phase locked loop 9 according to one embodiment of the invention. In this exemplary embodiment, the digital phase locked loop 9 is implemented in the form of an integrated circuit in a semiconductor body. The control loop 9 comprises a forward path having a digital phase detector 1, a digital filter 2 and a digitally controllable oscillator (DCO) 3.

The digital phase detector 1 has a reference input 11 and a feedback input 12. The output 13 of the digital phase detector 1 is connected to an input 21 of the digital filter 2. The output 22 of the digital filter 2 is connected to the actuating input 31 of the controllable oscillator 3. The output signal from the controllable oscillator 3 at the output 32 of the latter is, on the one hand, supplied to the output 7 of the digital phase locked loop and, on the other hand, is applied to the input 41 of a frequency divider 4 in a feedback path of the control loop.

The frequency divider 4 is, in one example, in the form of a multimodulus divider and comprises a control input 42 for setting a divider factor Nᵢ. The frequency divider 4 uses the oscillator signal which is supplied to the input and is at a first frequency f1 to generate a frequency-divided output signal at a second frequency f2. The ratio between the input frequency f1 and the output frequency f2 is set using the divider factor which is supplied to the control input 42. The frequency f2 of the divided output signal results from the ratio between the frequency f1 of the supplied oscillator signal and the divider factor Nᵢ. The signal DIV (whose frequency has been divided in this manner) at the output 43 of the frequency divider circuit 4 is supplied to the feedback input 12 of the digital phase detector.

In comparison with a purely analog implementation of a control loop or a mixed analog/digital implementation, a phase difference between the reference signal at the reference input 11 and the feedback signal at the feedback input 12 of the phase detector must be converted, with sufficient accuracy, into a digital control word in the digital phase locked loop illustrated.

In one embodiment of the invention, the phase detector of the digital phase locked loop has a plurality of inverters which are connected in series. A first inverter is connected to the feedback input of the digital phase detector. Provision is also made of a plurality of flip-flop circuits which are connected in series and the clock inputs of which are coupled to the reference input of the digital phase detector.

In one aspect of this embodiment, a data input of each of the series-connected flip-flop circuits is connected to a respective inverter output of the multiplicity of series-connected inverters.

In one embodiment of the invention, a decoder circuit is provided in the digital phase detector, wherein the decoder circuit is configured to supply an actuating pulse to the actuating output of the digital phase detector. In this case, the actuating pulse is configured from a delay between the occurrence of a clock edge of a signal at the feedback input of the digital phase detector and the occurrence of a clock edge of a signal at the reference input of the digital phase detector.

FIG. 2 shows one possible example of the digital phase detector. The phase detector contains a plurality of inverters I1, I2, I3, I4 to Im which are connected in series. In this case, as illustrated, the outputs of each inverter are connected to an input of the following inverter. For example, the output of the inverter I1 is thus coupled to the input of the inverter I2, the output of the inverter I2 is coupled to the input of the inverter I3 etc. The input of the inverter I1 is connected to the feedback input 12 of the digital phase locked loop.

The digital control loop also comprises a number of flip-flop circuits F1, F2, F3, F4 to Fm. A clock signal input C1 of each of the flip-flop circuits F1, F2, F3 to Fm is connected to the reference input 11 configured to receive the reference signal REF. In this embodiment, the reference signal REF is used as a clock signal to drive the individual flip-flop circuits. The data input 1D of each flip-flop is also connected to the output of a corresponding inverter circuit of the inverters I1, I2 to Im. The data input 1D of the first flip-flop F1 is thus connected to the data output of the first inverter I1. In a corresponding manner, the first data input 1D of the second flip-flop F2 is coupled to the output of the second inverter, the data input 1D of the third flip-flop F3 is coupled to the output of the third inverter I3, etc.

A decoder circuit 15 is additionally provided in the digital phase detector. The inputs 150, 151, 152 to 15m of the decoder circuit are connected, on the input side, to data outputs of the flip-flop circuits F1, F2, F3 to Fm. However, provision is made in this case for the inverted output Q̅ of each second flip-flop F1, F3 to Fm−1 to be connected to the decoder inputs 150, 152 to 15m−1. In a corresponding manner, the data outputs Q of the other flip-flops F2, F4 to Fm are connected to the inputs 151, 153 to 15m of the decoder circuit 15. The inverted data output Q̅ and the normal data output Q are thus alternately connected to the decoder circuit 15 beginning with the first flip-flop circuit F1.

During operation, the phase detector measures the fractional component of a delay between the reference signal at the reference input 11 and the next rising edge of the feedback clock signal at the input 12. The minimum resolution which can be achieved in this case corresponds to a delay of an individual inverter of the inverters I1, I2 to Im in the chain. The clock signal at the input 12 is passed through the individual inverters in the chain. The resultant delay is then sampled with the clock signal and supplied in the form of a thermometer code. This thermometer code is applied to the inputs 150, 151 to 15m of the decoder circuit, is converted into an actuating signal by the latter and is supplied to the output 13.

The phase detector thus generates a digitally coded word or a binary discrete-time output signal as the phase error signal. In this case, the phase error signal sweeps over a plurality of quantization stages in the phase detector and a step-shaped dependence of the phase error signal on the phase error thus results.

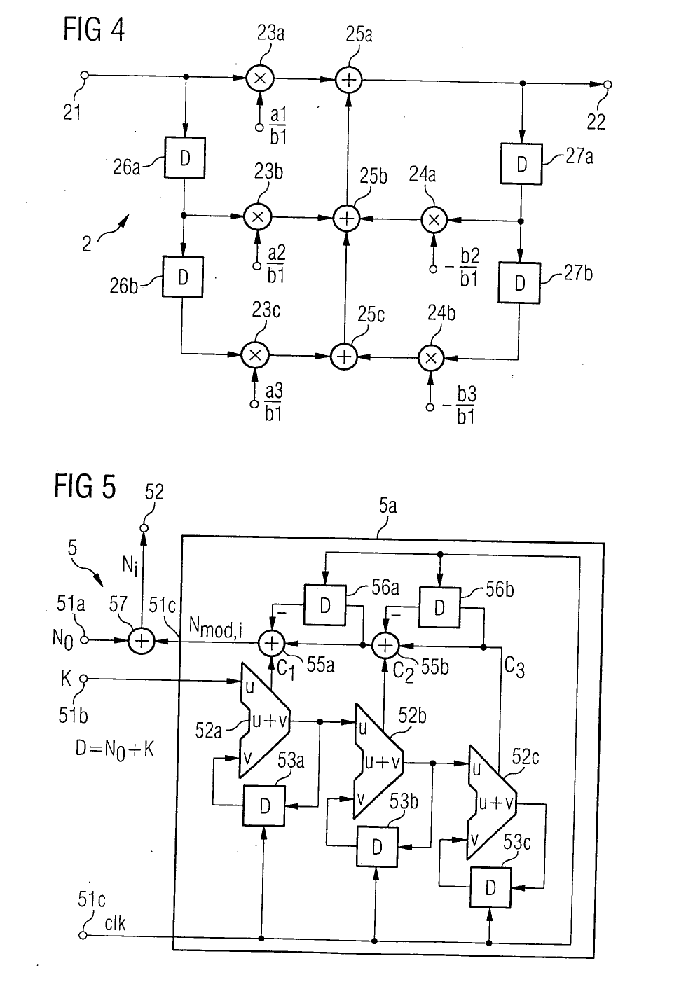

FIG. 4 shows one embodiment of a higher-order digital loop filter. The digital actuating signal supplied by the phase detector 1 is supplied to the input 21 of the digital loop filter 2. The digital loop filter 2 contains a number of multipliers 23a, 23b, 23c and 24a, 24b, a few delay elements 26a, 26b and 27a, 27b and three summation units 25a, 25b and 25c. The signal which is supplied to the input is multiplied, at the multiplication elements, by a factor which is respectively composed of a quotient of various coefficients. These coefficients a₁, a₂, a₃ and b₁, b₂ and b₃ are stored in a memory (not shown here).

The transmission response of the digital loop filter is determined using the individual coefficients and the quotients formed from the latter. As a result, the bandwidth of the digital loop filter may be changed on the basis of the coefficients, for example.

The input 21 of the loop filter 2 is connected to the first multiplier 23a, the output of which for its part is connected to the output 22 of the loop filter via a first summation unit 25a. Two further signal paths having the multipliers 23b, 24a and the summation unit 25b and having the multipliers 23c, 24b and the summation unit 25c are provided parallel to this signal path. In this case, the input of the multiplier 23b is connected to the input 21 of the filter 2 via a first delay element 26a and the multiplier 24a is connected to the output 22 of the filter 2 via a delay element 27a. The input of the multiplier 23c leads to the input of the multiplier 23b via an upstream delay element 26b. The output of the summation unit 25c whose inputs are connected to the outputs of the multipliers 23c and 24b is connected to the summation unit 25b. The output signals from the multipliers 23b, 24a are in turn supplied to said summation unit 25b which supplies them as a sum to the element 25a of the first path in the digital filter.

In another embodiment, the sigma-delta modulator comprises a cascaded sigma-delta converter having a data input for supplying the first component. The sigma-delta converter also contains a data output which is connected to a first input of a summing element. The second component of the data word is supplied to a second input of the summing element. The output of the summing element forms the actuating output of the sigma-delta modulator.

FIG. 5 shows one embodiment of the sigma-delta modulator 5 as is connected upstream of the frequency divider 4. The sigma-delta modulator (referred to as ΣΔ modulator for short) is configured using a third-order MASH modulator 5a (multistage noise shaping). It thus contains three modulator stages which are connected in series. The sigma-delta modulator is thus configured in such a manner that it can change between 8 values. This may be effected in the range from −3 to +4, for example. Alternatively, the sigma-delta modulator may be configured to supply a frequency setting word which has defined jitter and thus changes between at least two different values during a period of time.

In this example, a first data word N₀ which represents an integer component is supplied to the subinput 51a of the modulator 5a. A second subinput 51b is used to supply a fractional component K of the frequency word. In addition, the sigma-delta modulator 5 has a clock signal input 51c for supplying a clock signal clk. The subinput 51b is connected to the first modulator stage of the MASH modulator 5a.

Specifically, the subinput 51b is connected to a first accumulator 52a. The output of the accumulator 52a is in turn coupled to a first input of a second accumulator 52b whose output is connected to the third modulator stage of the MASH modulator 5a. The output u+v of the first accumulator 52a is also fed back to its second input v via a delay element 53a. In a corresponding manner, identically configured feedback is also provided in the second stage in the second summation unit 52b and in the third stage in the third summation unit 52c.

The accumulators 52a to 52c of the individual modulator stages of the MASH modulator 5a each have an overflow output which is connected to an input of a respective summation unit 55a and 55b in a feedback path. In this case, the overflow signal c2 from the second accumulator 52b is supplied, together with the overflow signal c3 from the third accumulator 52c, to the summation unit 55b. At the same time, the overflow signal c3 is supplied as a negative value to the summation unit 55b via a delay element 56b.

The output of the summation unit 55b is connected to an input of the first summation unit 55a. The latter adds the overflow signal c1 from the summation unit 52a to the result supplied by the summation unit 55b. In a corresponding manner, provision is also made here again of a delay element 56a whose input is connected to the output of the summation unit 55b and whose output is connected to the summation unit 55a. The result N_{mod,i} from the summation unit 55a, in which the errors have been reduced, is added to the integer component N₀ and is used as a channel word Nᵢ for setting the frequency divider 4.

During operation, the MASH modulator 5a illustrated introduces precisely defined jitter into the digital phase locked loop. The latter prevents an average divider factor that would divide the frequency of the oscillator signal in such a manner that the phase detector 1 is supplied with a frequency-divided signal which corresponds to a multiple of the reference signal. This excludes frequency division in the frequency divider, which divides the frequency of the feedback oscillator signal in such a manner that the frequency of the divided signal corresponds to a multiple of the reference frequency or is the same as the reference frequency.

In one embodiment of the invention, the data word supplied comprises a first component and a second component. In this case, the first component has a bit length having a number of bits. A last bit of the number of bits contains the value 1. The first component thus comprises a partial data word which contains the value 1 in its least significant bit. Configuring and supplying the second component to the sigma-delta modulator 5 thus generates, during operation of the digital phase locked loop, a frequency setting word which, on account of the special configuration of the first component, switches back and forth between at least two values. In this case, the changeover frequency between these two values is dependent on the bit length of the first component supplied.

The fractional component K of the channel word D itself has a bit width n. A channel word K[n] having a width of 8 bits (n=0, . . . , 7) can assume 256 different values. In order to ensure that the phase detector has sufficient accuracy for determining the phase error, the fractional component K of the channel word always has the value 1 for the least significant bit. Therefore: K[0]=1. This stipulation ensures that the MASH modulator 5a always generates an output signal N_{mod,i} which is different from zero.

Even in the case of a purely integer divider factor, the MASH modulator 5a adds the signal N_{mod,i} which is different from zero to the integer component N₀. As a result, the divider factor Nᵢ changes periodically, as a result of which the frequency of the feedback signal which is applied to the input 12 of the phase detector 1 is likewise changed. This results in a temporally changing value of the phase difference between the phase of the reference signal and the feedback signal. Since a plurality of quantization stages within the phase detector 1 detect this beat, a stable control signal can thus be generated again.

The sigma-delta modulator applies jitter to the phase error, which jitter should generally be greater than a quantization stage of the phase detector. This results, on average over time, in smoothing of the transfer function of the digital phase detector.

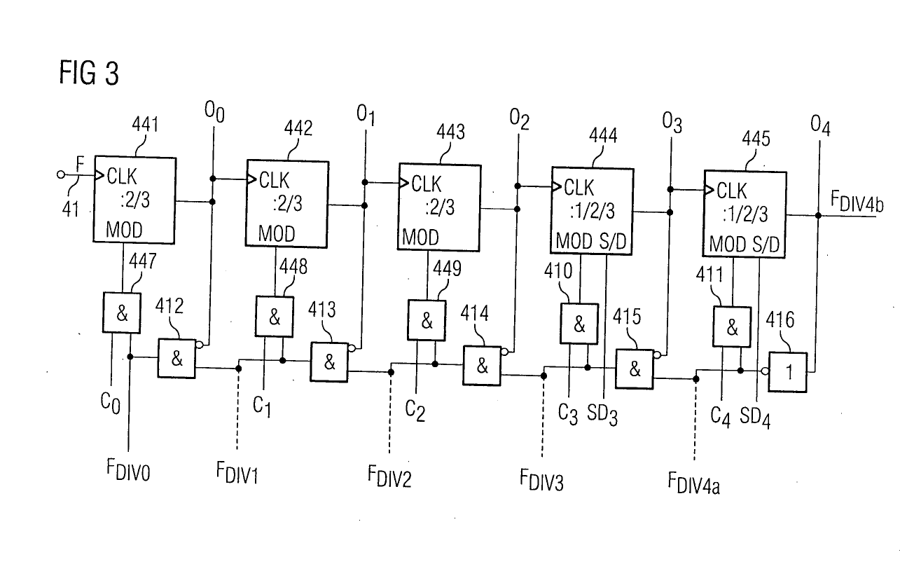

FIG. 3 shows one embodiment of the controllable frequency divider. In this case, the frequency divider 4 comprises a plurality of frequency divider stages 441 to 445 each having a clock input CLK, a signal output and a changeover input Mod. The changeover input Mod is used to preselect the frequency divider ratio. In this refinement, the first three frequency divider circuits 441, 442 and 443 are configured such that they can be changed over for changing over between the two divider values :2 and :3. The two frequency dividers 444, 445 at the output end additionally have a through-switching input S/D which switches the signal input to the signal output when activated. As a result, these two frequency dividers 444, 445 are additionally provided with a selectable frequency divider ratio of :1.

The signal output of the first frequency divider stage 441 is connected to the signal input of the second frequency divider stage 442 whose signal output is connected to the signal input of the third frequency divider stage 443 etc. The output of the last frequency divider stage 445 is marked with the reference symbol F_{Div4b}. The signal outputs are also connected to the taps O₀ to O₄. The frequency-divided signal may be tapped off at said taps and routed out of the frequency divider circuit.

The output of a respective logic AND gate 447, 448, 449, 410 and 411 is also coupled to each changeover input MOD of the frequency divider stages 441 to 445 for supplying a changeover signal. The AND gates 447 to 411 each have two inputs. The first inputs of the AND gates are respectively connected to one of the connections C₀ to C₄ for connection to a respective control output of a decoder circuit which is not shown in any more detail and, for its part, is supplied with the frequency word Nᵢ from the MASH modulator 5a. The respective second inputs of the AND gates 447 to 410 are respectively connected to an output of further logic AND gates 412, 413, 414 and 415. The second input of the AND gate 411 is connected to the output of an inverter 416 whose input is connected to the signal output F_{Div4b} of the frequency divider 445 at the output end.

The AND gates 412 to 415 also each have two inputs. The respective first input of the AND gates 412 to 415 is in the form of an inverting input and is respectively connected to the output of the associated frequency divider 441 to 444. The second input of the AND gates 412 to 415 is respectively connected to the output of the AND gate 413 to 415 which is associated with the downstream frequency divider stage 442 to 445 and, in the case of the gate 415, to the output of the inverter 416. The outputs of the AND gates 412 to 415 and the output of the inverter 416 form a respective tap node for tapping off an output signal from the frequency-dividing circuit arrangement, which tap nodes are denoted using F_{Div0}, F_{Div1} to F_{Div4a} in the present case.

The signal output F_{Div0} is used in the present case as the output of the frequency divider circuit 4, at which a signal whose frequency has been divided down with respect to the input signal frequency f1 can be discharged. This makes it possible for the divider circuit to precisely indicate the delay between the nth input edge and the divider output edge triggered thereby. The use of the 1/2/3 divider stages 444, 445 allows the lower limit of the adjustable divider range to be extended. It goes without saying that the frequency divider illustrated may be extended by additional divider stages, with the result that the divider range can be extended. The frequency channel word which has been conditioned and supplied by the MASH modulator 5a is in turn applied to the control connections C₀ to C₄.

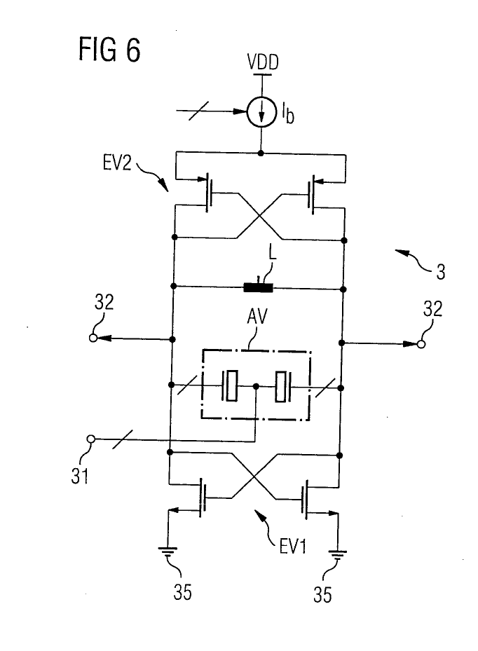

FIG. 6 shows an exemplary oscillator which can be tuned to discrete values. The oscillator contains, as a resonance-determining and frequency-determining component, a coil L and an array of a plurality of switchable varactors AV. For the purpose of damping reduction, the oscillator contains two damping reduction amplifiers comprising field effect transistors. A first connection of a first pair of field effect transistors EV1 is connected to the ground potential connection 35. The control connections of each transistor are respectively coupled to the second connection of the respective other transistor via cross-coupling.

In a symmetrical manner, a respective first connection of the second pair of transistors EV2 is connected to a current source IB and to the supply potential VDD so as to form a common node. The control connections of the two transistors of the second damping reduction amplifier EV2 are likewise connected to the second connection of the respective other transistor so as to form a cross-coupling. Output taps 32 are additionally provided in the resonant circuit, at which the output signal from the digitally adjustable oscillator 3 can be tapped off.

During operation, the digital setting signal is supplied to the control input 31. Said setting signal switches some varactors of the frequency-determining array AV into the resonant circuit, with the result that the output frequency of the entire oscillator circuit is changed.

Introducing precisely defined jitter thus avoids a stability problem in the present digital phase locked loop on account of the phase detector being controlled using only one quantization stage. In this case, precisely defined jitter is introduced by supplying a frequency word to a sigma-delta modulator which uses it to generate the frequency setting word Nᵢ for setting the divider ratio in the divider circuit 4. The frequency word K supplied represents a fractional component of the channel setting word. The embodiment illustrated enables simple implementation, there being no need for any additional compensation for the loop filter parameters of the loop filter 2, for example. Very high temporal resolution is simultaneously achieved using the phase detector.

While the invention has been illustrated and described with respect to one or more implementations, alterations and/or modifications may be made to the illustrated examples without departing from the spirit and scope of the appended claims. In particular regard to the various functions performed by the above described components or structures (assemblies, devices, circuits, systems, etc.), the terms (including a reference to a “means”) used to describe such components are intended to correspond, unless otherwise indicated, to any component or structure which performs the specified function of the described component (e.g., that is functionally equivalent), even though not structurally equivalent to the disclosed structure which performs the function in the herein illustrated exemplary implementations of the invention. In addition, while a particular feature of the invention may have been disclosed with respect to only one of several implementations, such feature may be combined with one or more other features of the other implementations as may be desired and advantageous for any given or particular application. Furthermore, to the extent that the terms “including”, “includes”, “having”, “has”, “with”, or variants thereof are used in either the detailed description and the claims, such terms are intended to be inclusive in a manner similar to the term “comprising”.

1. A digital phase locked loop comprising:
a digital phase detector having a feedback input, a reference input, and an actuating output;
a digital filter having an input coupled to the actuating output of the digital phase detector;
a discrete value tunable oscillator having an actuating input coupled to an output of the digital filter;
a feedback path comprising a frequency divider circuit having an actuating input, and configured to set a divider ratio associated therewith, wherein an input of the frequency divider is connected to the oscillator, and an output of the frequency divider circuit is connected to the feedback input of the digital phase detector; and
a sigma-delta modulator having a data input configured to receive a data word and having an actuating output configured to supply a frequency setting word to the actuating input of the frequency divider based on the data word;
wherein the data word is a constant value during a predetermined period of time, and wherein the sigma-delta modulator is configured to generate the frequency setting word that changes during the predetermined period of time.

2. The digital phase locked loop of claim 1, wherein the phase detector comprises a plurality of inverters that are connected in series, wherein a first inverter is connected to the feedback input and wherein the phase detector comprises a plurality of flip-flop circuits that are connected in series and the clock inputs of which are connected to the reference input.

3. The digital phase locked loop of claim 1, wherein the phase detector comprises a decoder circuit configured to supply an actuating pulse to the actuating output, wherein the actuating pulse is derived from a delay between the occurrence of a clock edge of a signal at the feedback input and the occurrence of a clock edge of a signal at the reference input.

4. The digital phase locked loop of claim 1, wherein the data word comprises a first component and a second component, wherein the first component has a bit length having a plurality of bits, a last bit thereof containing the value 1.

5. The digital phase locked loop of claim 4, wherein the sigma-delta modulator comprises a cascaded sigma-delta converter that comprises a data input configured to receive the first component, and a data output connected to a first input of a summing element, a second input of which is configured to receive the second component, and an output of which forms the actuating output.

6. A digital phase locked loop comprising:
a digital phase detector configured to compare a reference signal with a frequency-divided feedback signal and generate an actuating signal based thereon;
a digital filter configured to generate an actuating word by filtering the actuating signal;
a digitally controlled oscillator configured to generate an oscillator signal based on the actuating word;
an adjustable frequency divider configured to divide the frequency of the oscillator signal using a divider ratio that depends on a frequency setting word; and
a sigma-delta modulator configured to generate the frequency setting word based on the basis of a data word, wherein the frequency setting word has a defined jitter and changes between at least two different values during a period of time.

7. The digital phase locked loop of claim 6, wherein the data word supplied in the period of time is constant, and wherein the frequency setting word changes during the time period.

8. The digital phase locked loop of claim 6, wherein the data word comprises a first component and a second component, and wherein the first component has a bit length having a plurality of bits, a last bit of the plurality of bits containing the value 1.

9. The digital phase locked loop of claim 6, wherein the sigma-delta modulator is configured as a cascaded sigma-delta converter.

10. A method for controlling a digital phase locked loop, comprising:
providing a digital phase locked loop having an adjustable frequency divider in a feedback path;
providing a data word having a first component and a second component, wherein the first component has a value that is greater than or equal to 1;
generating a frequency setting word from the first and second components, wherein the second frequency setting word has jitter that is derived from the first component; and
supplying the frequency setting word to the frequency divider.

11. The method of claim 10, wherein the frequency setting word is generated using sigma-delta modulation.

12. A method for generating an oscillator signal, comprising:
comparing a reference signal with a frequency-divided oscillator signal;
filtering the comparison result;
driving a digitally controlled oscillator based on the filtering result, thereby generating the oscillator signal;
generating a frequency setting word, using sigma-delta modulation, from a data word, the frequency setting word having jitter; and
dividing the frequency of the oscillator signal using a divider ratio that depends on the frequency setting word.

13. The method of claim 12, wherein the data word which is supplied in a period of time is constant, and wherein the frequency setting word changes during this period of time is generated using the sigma-delta modulation.

14. The method of claim 12, wherein the data word comprises a first component and a second component and the first component has a bit length having a plurality of bits, a last bit of the plurality of bits containing the value 1.

15. The method of claim 12, wherein the comparison operation is effected using a digital phase detector.

16. The method of claim 12, wherein the filtering operation is effected using a digital filter.

17. A digital phase locked loop, comprising
means for comparing a reference signal with a frequency-divided oscillator signal;
means for filtering the comparison result;
means for generating an oscillator signal based on the filtered comparison result;
means for generating a frequency setting word using sigma-delta modulation from a data word, wherein the generated frequency setting word has jitter; and
means for dividing the frequency of the oscillator signal using a divider ratio that depends on the frequency setting word.

18. The digital phase locked loop of claim 17, wherein the filtering means comprises a digital filtering means.

19. The digital phase locked loop of claim 17, wherein the comparison means comprises a digital phase detector.

20. The digital phase locked loop of claim 17, wherein the data word supplied in a period of time is constant, and wherein the frequency setting word changes during this period of time using the sigma-delta modulation.

21. The digital phase locked loop of claim 17, wherein the data word comprises a first component and a second component, and wherein the first component has a bit length having a plurality of bits, a last bit of the plurality of bits containing the value 1.
